(19) United States
(12) Patent Application Publication
(10) Pub. No.: US 2016/0240552 A1
(43) Pub. Date: Aug. 18, 2016

(54) SEMICONDUCTOR MEMORY DEVICE AND METHOD FOR MANUFACTURING SAME

(71) Applicant: Kabushiki Kaisha Toshiba, Minato-ku (JP)

(72) Inventor: Shinya ARAI, Yokkaichi (JP)

(73) Assignee: Kabushiki Kaisha Toshiba, Minato-ku (JP)

(21) Appl. No.: 14/729,161

(22) Filed: Jun. 3, 2015

Related U.S. Application Data
(60) Provisional application No. 62/115,940, filed on Feb. 13, 2015.

(51) Int. Cl. H01L 27/115; H01L 21/28

(52) U.S. Cl. CPC H01L 27/11582; H01L 21/28282

(57) ABSTRACT

According to one embodiment, a semiconductor memory device includes a substrate; a conductive layer provided on the substrate; a stacked body provided on the conductive layer and including a plurality of electrode layers separately stacked each other; a coupling portion provided in the conductive layer; a semiconductor portion provided integrally in the stacked body and in the coupling portion; a charge storage film provided between the semiconductor portion and the plurality of electrode layers; and an interconnect portion provided integrally in the stacked body and in the conductive layer and extending in a stacking direction of the stacked body. The interconnect portion includes a side surface provided in the conductive layer, and the side surface is in contact with an entire side surface of the semiconductor portion in the coupling portion.

This application is based upon and claims the benefit of priority from U.S. Provisional Patent Application 62/115,940 field on Feb. 13, 2015; the entire contents of which are incorporated herein by reference.

### FIELD

Embodiments described herein relate generally to a semiconductor memory device and a method for manufacturing same.

### BACKGROUND

A memory device having a three-dimensional structure has been proposed, in which memory holes are formed in a stacked body including a plurality of electrode layers that function as control gates in memory cells and are stacked via an insulating layer, and a silicon body serving as a channel is provided on a side wall of the memory hole via a charge storage film.

For the stacked body in such a three-dimensional device, the memory hole and a contact to be connected to the memory hole are formed by, for example, a RIE (Reactive Ion Etching) method. In this case, the degree of difficulty in processing may be increased with the miniaturization of the three-dimensional device.

### BRIEF DESCRIPTION OF THE DRAWINGS

FIG. 1 is a schematic perspective view of a memory cell array of an embodiment;

FIG. 2A is a schematic cross-sectional view of a part of a memory string of the embodiment and FIG. 2B is a schematic plan view of the memory string of the embodiment;

FIG. 3A is an enlarged schematic cross-sectional view of a part of a columnar portion of the embodiment and FIG. 3B is an enlarged schematic cross-sectional view of a part of the memory string of the embodiment;

FIG. 4A to FIG. 13B are schematic views showing a method for manufacturing the semiconductor memory device of the embodiment;

FIG. 14A is a schematic cross-sectional view of a part of the memory string of another embodiment and FIG. 14B is an enlarged schematic cross-sectional view of a part of the memory string of the another embodiment; and

FIG. 15A to FIG. 18B are schematic views showing the method for manufacturing the semiconductor memory device of the another embodiment.

### DETAILED DESCRIPTION

According to one embodiment, a semiconductor memory device includes a substrate; a conductive layer provided on the substrate; a stacked body provided on the conductive layer and including a plurality of electrode layers separately stacked each other; a coupling portion provided in the conductive layer; a semiconductor portion provided integrally in the stacked body and in the coupling portion; a charge storage film provided between the semiconductor portion and the plurality of electrode layers; and an interconnect portion provided integrally in the stacked body and in the conductive layer and extending in a stacking direction of the stacked body. The interconnect portion includes a side surface provided in the conductive layer, and the side surface is in contact with an entire side surface of the semiconductor portion in the coupling portion.

Hereinafter, embodiments will be described with reference to the drawings. In the drawings, the same elements are denoted by the same reference sign.

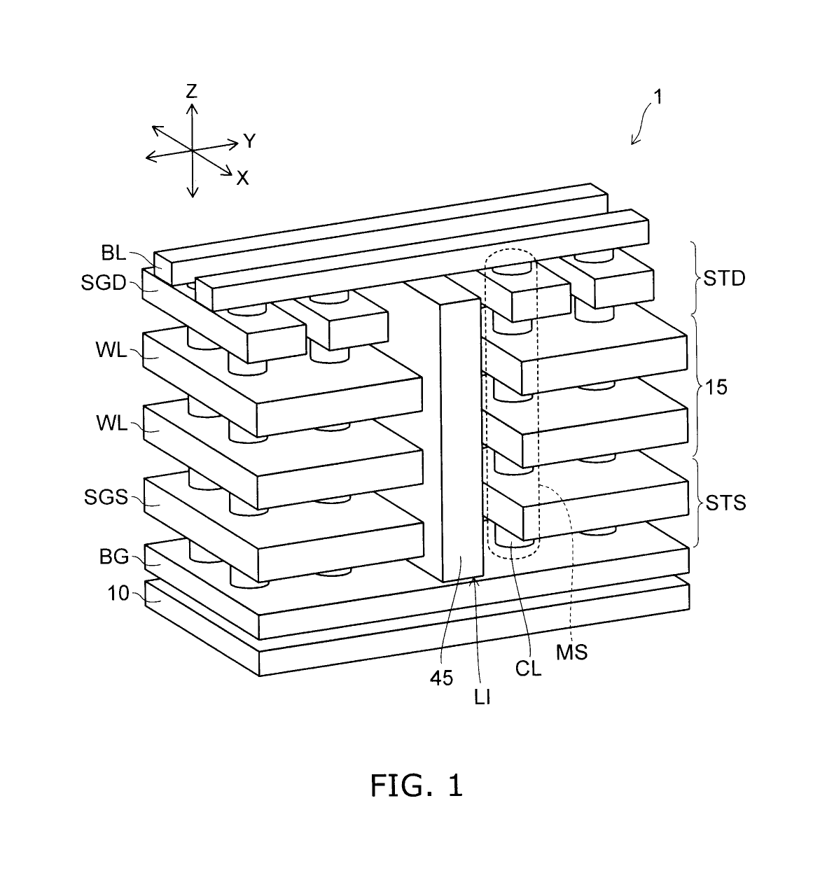

FIG. 1 is a schematic perspective view of a memory cell array 1 of the embodiment. In FIG. 1, insulating layers and the like are not shown for the sake of clarity of the drawing.

In FIG. 1, two directions parallel to a major surface of a substrate 10 and orthogonal to each other are defined as an X-direction and a Y-direction, and a direction orthogonal to both the X-direction and the Y-direction is defined as a Z-direction (stacking direction).

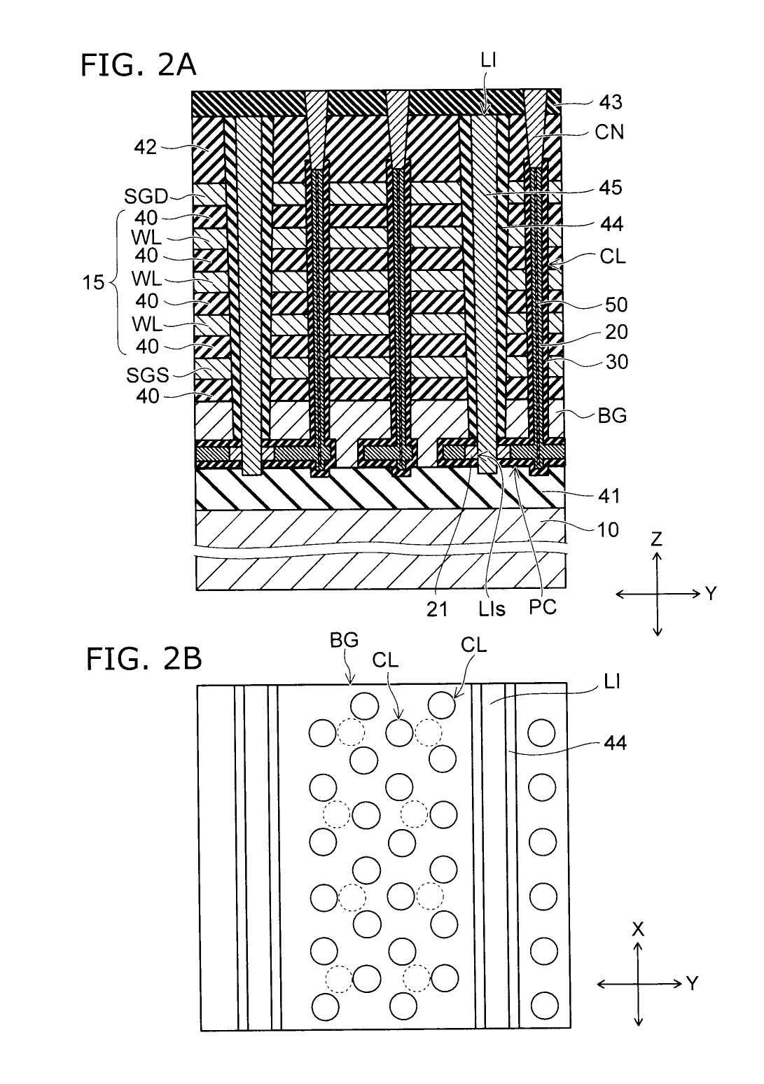

The memory cell array 1 includes a plurality of memory strings MS. FIG. 2A is a schematic cross-sectional view of a portion of the memory string MS of the embodiment. FIG. 2A shows a cross-section parallel to a YZ plane in FIG. 1. FIG. 2B is a schematic plan view of the memory string MS. FIG. 2B shows an upper surface of a back gate BG parallel to an XY plane in FIG. 1.

As shown in FIG. 1 and FIG. 2A, the back gate BG (conductive layer) is provided on the substrate 10. A source-side select gate SGS is provided on the back gate BG via an insulating layer 40. A stacked body 15 is provided on the source-side select gate SGS.

The back gate BG includes silicon doped with, for example, boron.

The stacked body 15 includes a plurality of electrode layers WL and a plurality of insulating layers 40. The plurality of electrode layers WL are separately stacked each other, and the plurality of insulating layers 40 are each provided between the plurality of electrode layers WL.

The plurality of electrode layers WL and the plurality of insulating layers 40 are, for example, each alternately stacked. The number of the electrode layers WL shown in the drawing is merely an example, and the number of the electrode layers WL may be arbitrary.

The uppermost layer of the stacked body 15 is the insulating layer 40. A drain-side select gate SGD is provided on the insulating layer 40 in the uppermost layer.

The source-side select gate SGS, the drain-side select gate SGD, and the electrode layer WL include, for example, a metal. The source-side select gate SGS, the drain-side select gate SGD, and the electrode layer WL are, for example, silicon layers including silicon as a main component, and the silicon layer is doped with, for example, boron as an impurity to provide conductivity. Moreover, the source-side select gate SGS, the drain-side select gate SGD, and the electrode layer WL may include metal silicide.

For example, the insulating layer 40 includes an insulating film mainly including silicon oxide. The insulating layer 40 may include, for example, an air gap.

The thickness of each of the drain-side select gate SGD and the source-side select gate SGS is larger than the thickness of one electrode layer WL, and, for example, a plurality of layers of the drain-side select gate SGD and the source-side select gate SGS may be provided. For example, the thickness of each of the drain-side select gate SGD and the source-side select gate SGS may be the same as or less than the thickness of one electrode layer WL, in which case a plurality of layers of layers of the drain-side select gate SGD and the source-side select gate SGS may be provided similarly to the above. The “thickness” as used herein represents the thickness in the stacking direction (the Z-direction) of the stacked body 15.

The stacked body 15 is provided with columnar portions CL extending in the Z-direction. The columnar portion CL penetrates the stacked body 15. The columnar portion CL is formed in, for example, a circular cylindrical or elliptical cylindrical shape.

The stacked body 15 is provided with interconnect portions LI penetrating the stacked body 15 and the back gate BG and extending in the X-direction and the Z-direction. An insulating film 44 is provided on a side wall of the interconnect portion LI, and a conductive film 45 is provided inside the insulating film 44. The insulating film 44 and the conductive film 45 extend in the X-direction and the Z-direction similarly to the interconnect portion LI. The conductive film 45 includes, for example, at least any of tungsten, titanium, and titanium nitride.

The interconnect portion LI is electrically connected with the columnar portion CL via a coupling portion PC provided in the back gate BG. An upper end of the interconnect portion LI is electrically connected with a control circuit (not shown).

The coupling portion PC spreads in the XY plane. The coupling portion PC is provided integrally with the columnar portion CL. The coupling portion PC is provided integrally with, for example, more than one columnar portion CL. The phrase “provided integrally with” represents that a portion of a material used for the columnar portion CL extends to the coupling portion PC.

The coupling portion PC covers a portion of the interconnect portion LI and electrically connects the columnar portion CL with the interconnect portion LI. An insulating film (memory film 30 described later) is provided on a side wall of the coupling portion PC. For this reason, the coupling portion PC is not electrically connected with the back gate BG. For example, a bottom surface of the interconnect portion LI may be provided in the coupling portion PC. The coupling portion PC covers a column portion of back gate BG (see dotted-line circle in FIG. 2B). As shown in FIG. 2B, for example, the coupling portion of back gate BG is provided between the columnar portions CL.

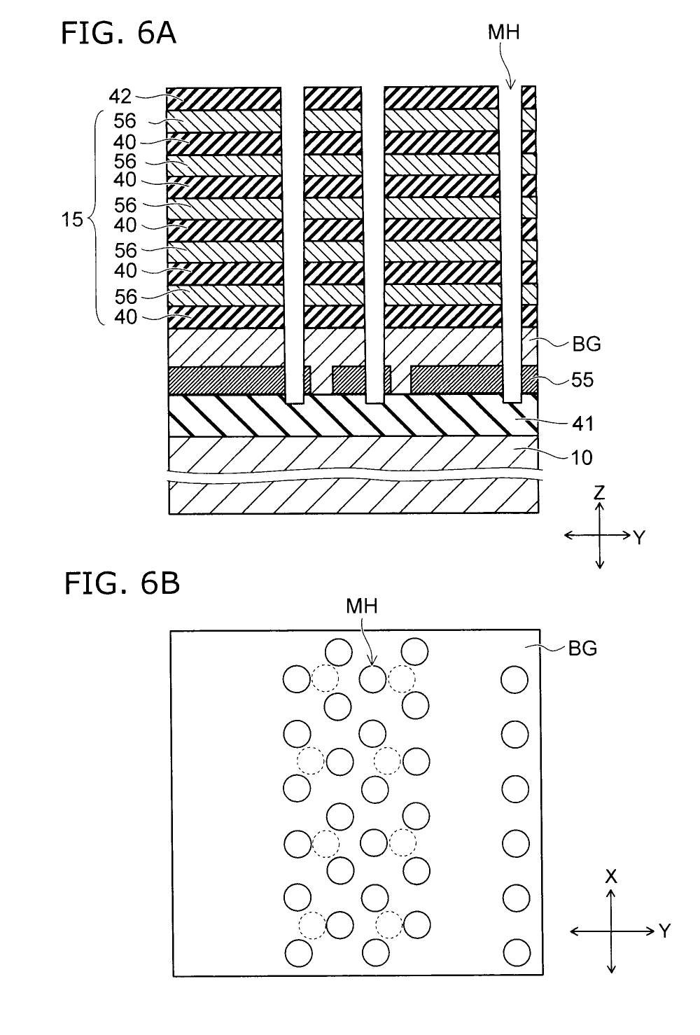

The columnar portion CL is formed in each of memory holes MH (FIG. 6A) formed in the stacked body 15 including the plurality of electrode layers WL and the plurality of insulating layers 40. In the memory hole MH, a channel body 20 (semiconductor pillar portion) as a semiconductor channel is provided. The channel body 20 is also provided in the coupling portion PC (semiconductor portion).

The memory film 30 is provided between the stacked body 15 and the channel body 20. That is, the channel body 20 is surrounded by the electrode layers WL via the memory film 30. The memory film 30 is also provided between an inner wall of the coupling portion PC and the channel body 20.

The channel body 20 is, for example, a silicon film including silicon as a main component. One end (upper end) of the channel body 20 is connected to a bit line BL (interconnect) shown in FIG. 1, while the other end of the channel body 20 is provided in the coupling portion PC and is in contact with the interconnect portion LI. Each bit line BL extends in the Y-direction.

A drain-side select transistor STD is provided at an upper end portion of the columnar portion CL in the memory string MS, while a source-side select transistor STS is provided at a lower end portion.

Memory cells MC, the drain-side select transistor STD, and the source-side select transistor STS are vertical transistors in which a current flows in the stacking direction (the Z-direction) of the stacked body 15.

The drain-side select gate SGD functions as a gate electrode (control gate) of the drain-side select transistor STD. An insulating film that functions as a gate insulating film of the drain-side select transistor STD is provided between the drain-side select gate SGD and the channel body 20

The source-side select gate SGS functions as a gate electrode (control gate) of the source-side select transistor STS. An insulating film that functions as a gate insulating film of the source-side select transistor STS is provided between the source-side select gate SGS and the channel body 20.

The plurality of memory cells MC using the respective electrode layers WL as control gates are provided between the drain-side select transistor STD and the source-side select transistor STS.

The plurality of memory cells MC, the drain-side select transistor STD, and the source-side select transistor STS are connected in series through the channel body 20 to configure one memory string MS. The plurality of memory strings MS are arranged in the X-direction and the Y-direction, whereby the plurality of memory cells MC are three-dimensionally provided in the X-direction, the Y-direction, and the Z-direction.

The semiconductor memory device of the embodiment can electrically freely erase or write data, and can hold a memory content even if power is off.

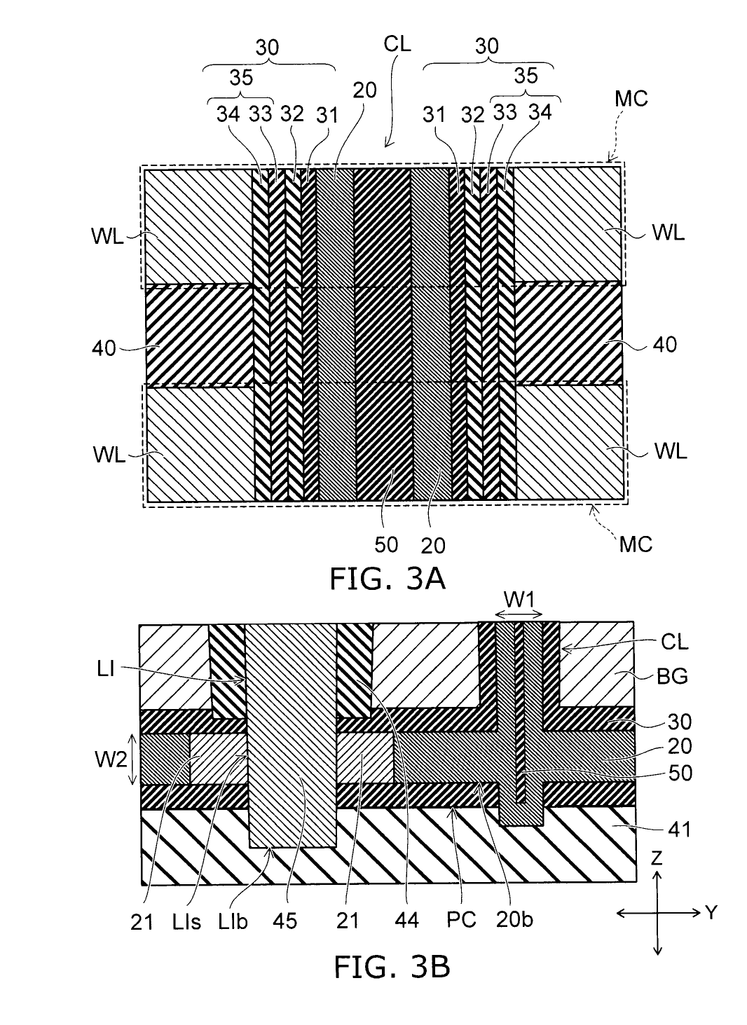

FIG. 3A is an enlarged schematic cross-sectional view of a portion of the columnar portion CL of the embodiment. An example of the memory cell MC of the embodiment will be described with reference to FIG. 3A.

The memory cell MC is of, for example, a charge trap type, and includes the electrode layer WL, the memory film 30, the channel body 20, and a core insulating film 50.

The memory film 30 and the channel body 20 are provided between the electrode layer WL and the core insulating film 50. Inside the channel body 20, for example, the core insulating film 50 is provided. The channel body 20 may have, for example, a columnar shape. Inside the channel body 20, the core insulating film 50 may not be provided.

The channel body 20 functions as a channel in the memory cell MC, and the electrode layer WL functions as a control gate of the memory cell MC. A charge storage film 32 functions as a data memory layer that stores charge injected from the channel body 20. That is, at each of crossing portions between the channel body 20 and the electrode layers WL, the memory cell MC having a structure in which the control gate surrounds the channel is formed.

The memory film 30 includes, for example, a block insulating film 35, the charge storage film 32, and a tunnel insulating film 31. The block insulating film 35 is in contact with the electrode layer WL. The tunnel insulating film 31 is in contact with the channel body 20. The charge storage film 32 is provided between the block insulating film 35 and the tunnel insulating film 31.

The block insulating film 35 prevents the charge stored in the charge storage film 32 from diffusing into the electrode layer WL. The block insulating film 35 includes a block film 33 and a cap film 34.

The block film 33 is provided between the cap film 34 and the charge storage film 32. The block film 33 is, for example, a silicon oxide film.

The cap film 34 is provided in contact with the electrode layer WL. As the cap film 34, a film having a higher permittivity than that of the block film 33 is used, the cap film 34 includes, for example, at least any of a silicon nitride film and aluminum oxide. By providing the cap film 34 so as to be in contact with the electrode layer WL, it is possible to suppress back-tunneling electrons injected from the electrode layer WL in erasing. That is, the stacked film of a silicon oxide film and a silicon nitride film is used as the block insulating film 35, so that charge blocking property can be enhanced.

The charge storage film 32 has many trap sites to trap charge, and is, for example, a silicon nitride film.

The tunnel insulating film 31 serves as a potential barrier when charge is injected from the channel body 20 into the charge storage film 32 or when the charge stored in the charge storage film 32 diffuses into the channel body 20. The tunnel insulating film 31 is, for example, a silicon oxide film.

Alternatively, as the tunnel insulating film 31, a stacked film (ONO film) having a structure in which a silicon nitride film is interposed between a pair of silicon oxide films may be used. When the ONO film is used as the tunnel insulating film 31, an erase operation can be performed at a low electric field, compared to a single layer of silicon oxide film.

FIG. 3B is an enlarged schematic cross-sectional view of a portion of the memory string of the embodiment.

As shown in FIG. 2A and FIG. 3B, the memory film 30 and the channel body 20 are integrally provided from within the columnar portion CL to within the coupling portion PC. The memory film 30 is provided on the side wall of the coupling portion PC. The channel body 20 is provided inside the memory film 30, and provided in the back gate BG via the memory film 30 (insulating film). That is, the semiconductor portion, which is a portion of the channel body 20 provided in the back gate BG with the insulating film between the portion of the channel body and the back gate BG, is provided integrally with the semiconductor pillar portion, which is a portion of the channel body 20 provided along the stacking direction of the stacked body 15.

The channel body 20 in the coupling portion PC has, for example, a columnar shape, and is provided in the coupling portion PC without gaps.

The interconnect portion LI includes a side surface LIs and a lower surface LIb (first lower surface). The side surface LIs, which is in contact with the entire side surface of the channel body 20 in the coupling portion PC, is provided with the conductive film 45 but not provided with the insulating film 44. Therefore, the conductive film 45 is in contact with the channel body 20. The lower surface LIb is in contact with an insulating layer 41, and is not connected with the channel body 20 in the coupling portion PC.

The channel body 20 in the coupling portion PC includes a lower surface 20b (second lower surface) whose height is higher than the lower surface LIb of the interconnect portion LI, and an impurity layer 21 in contact with the side surface LIs. The side surface LIs is electrically connected with the channel body 20 via the impurity layer 21 in the coupling portion PC. The impurity layer 21 includes an impurity, and the impurity concentration of the impurity layer 21 is higher than the impurity concentration of the channel body 20. As the impurity included in the impurity layer 21, for example, boron is used.

In the coupling portion PC, for example, the core insulating film 50 is not provided. That is, the core insulating film 50 is provided only in the columnar portion CL, and extends in the Z-direction. In this case, the interconnect portion LI is separated from the core insulating film 50. Due to this, the impurity layer 21 can be brought into contact with the entire surface of the side surface LIs, so that the contact area of the side surface LIs with the impurity layer 21 can be increased.

The interconnect portion LI is covered with the channel body 20 in the coupling portion PC.

The bit lines BL shown in FIG. 1 are provided on the drain-side select gate SGD via insulating layers 42 and 43. The bit line BL is connected with the upper ends of the channel bodies 20 each via a contact portion CN penetrating the insulating layers 42 and 43. The upper end of the interconnect portion LI is connected with a source interconnect (not shown).

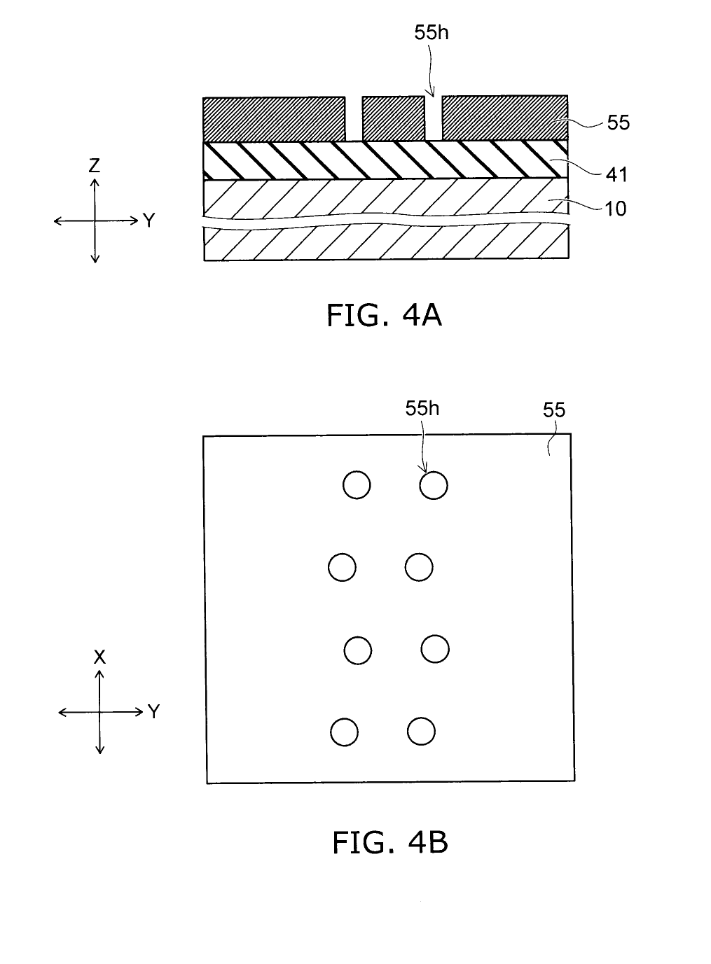

Next, a method for manufacturing the semiconductor memory device of the embodiment will be described with reference to FIG. 4A to FIG. 13B.

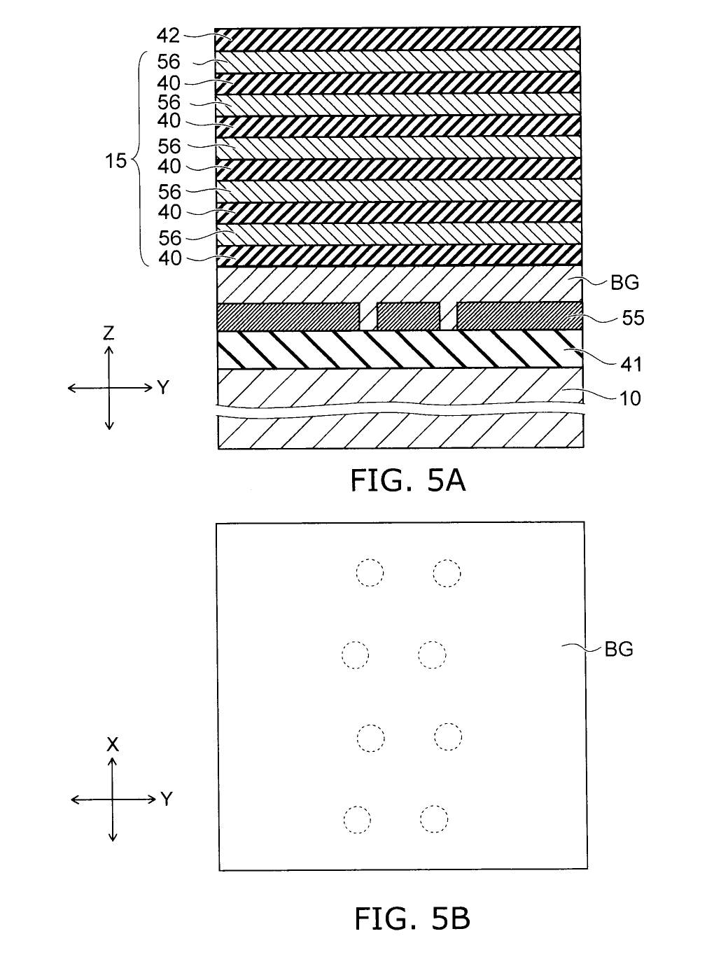

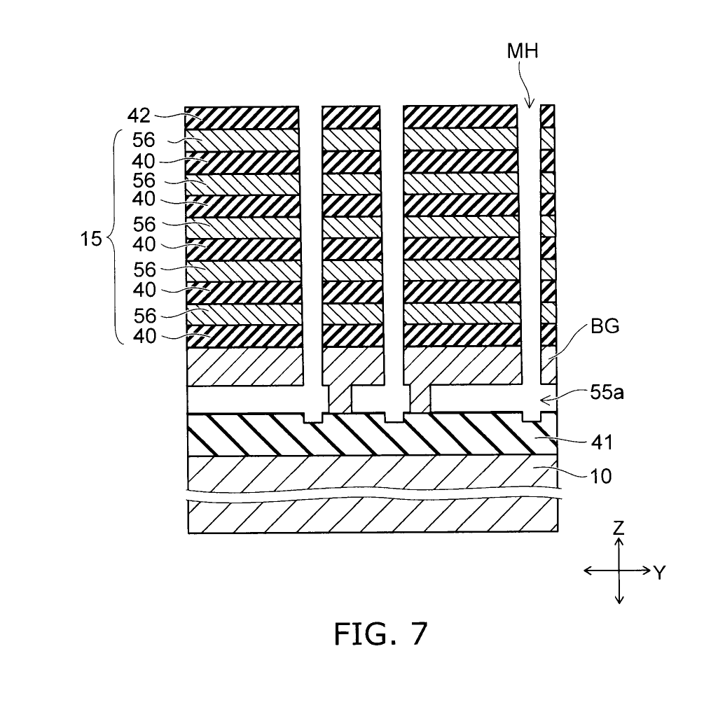

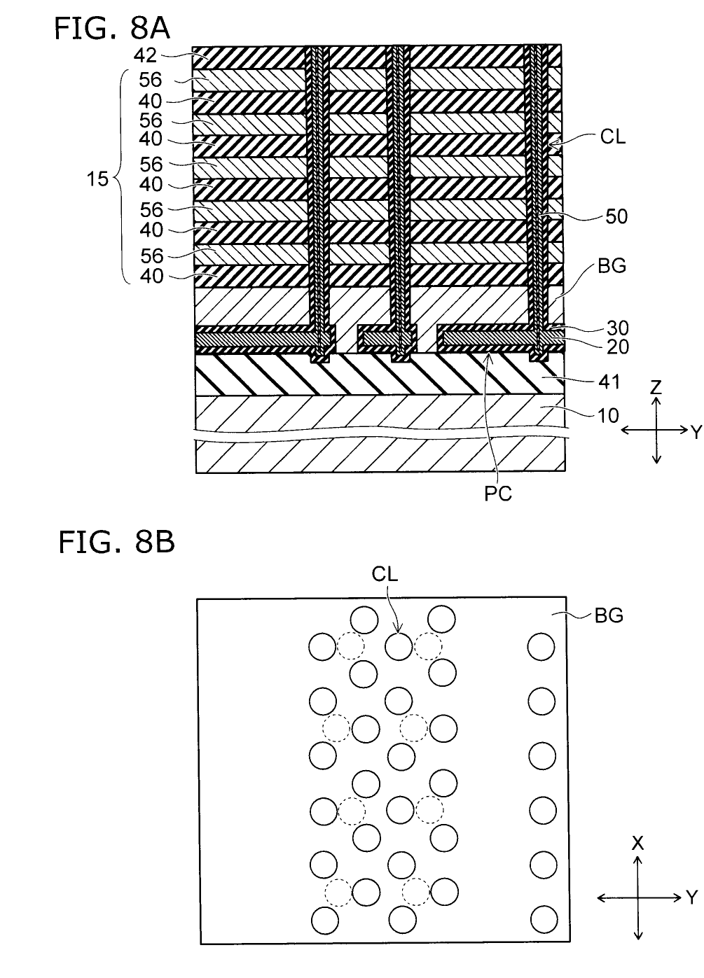

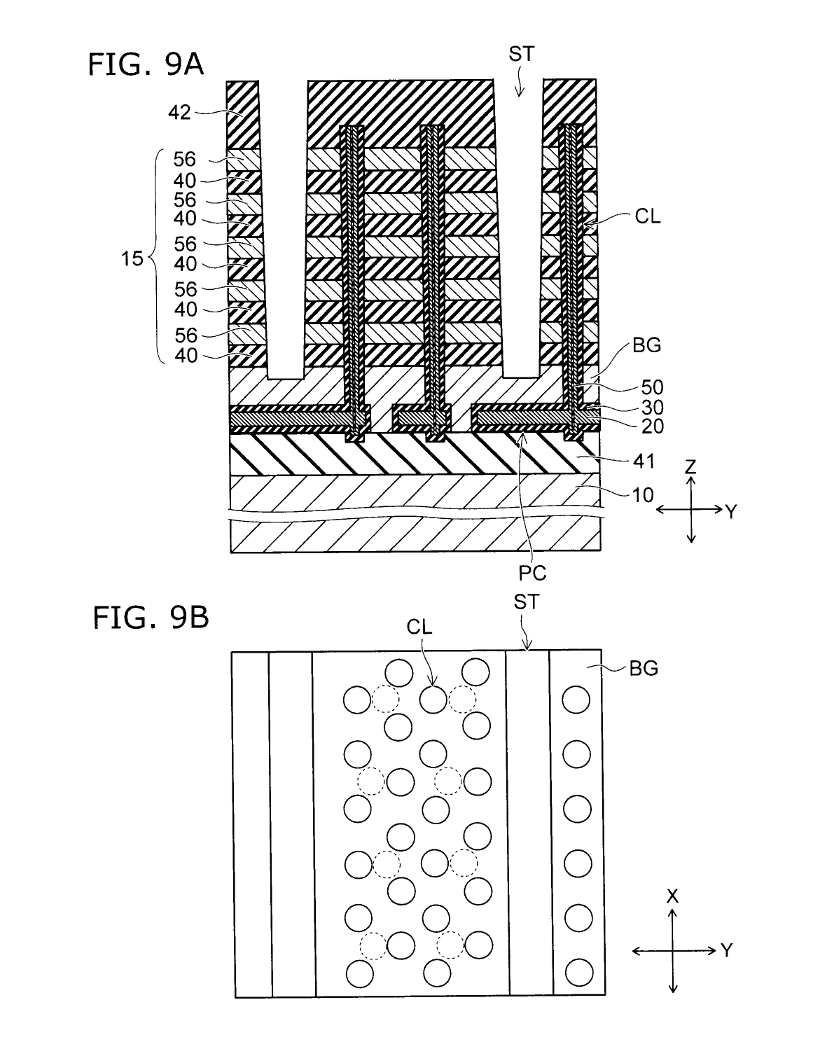

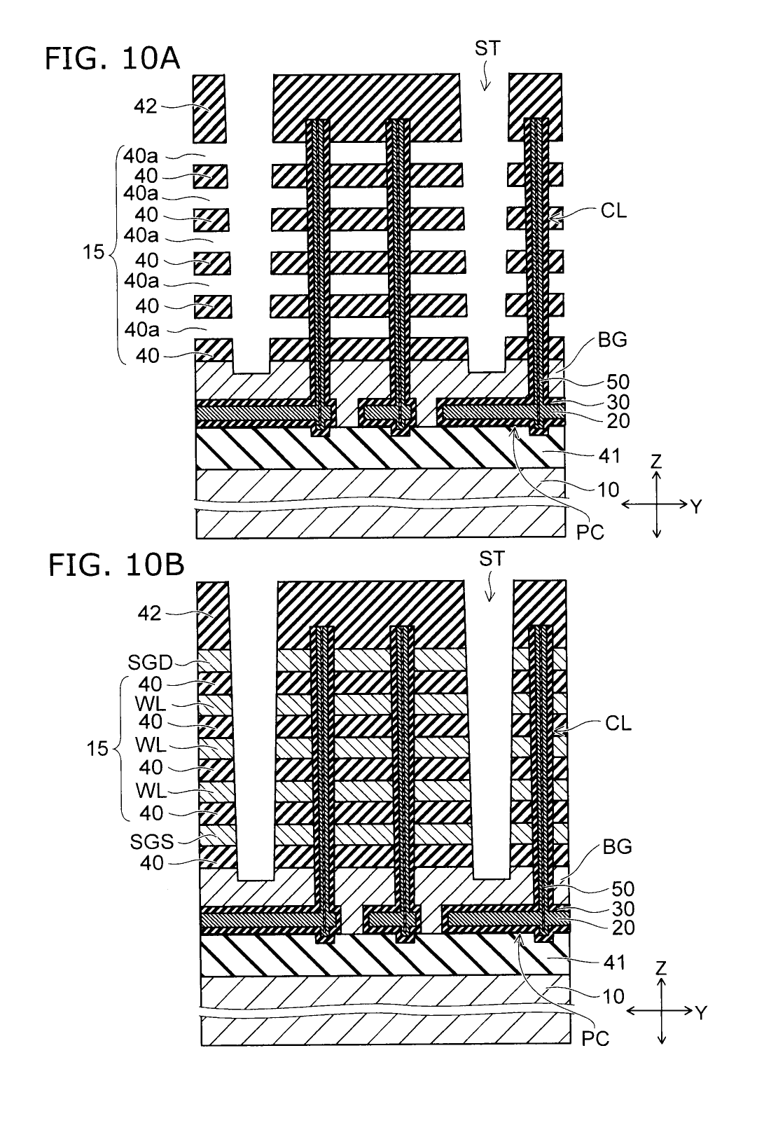

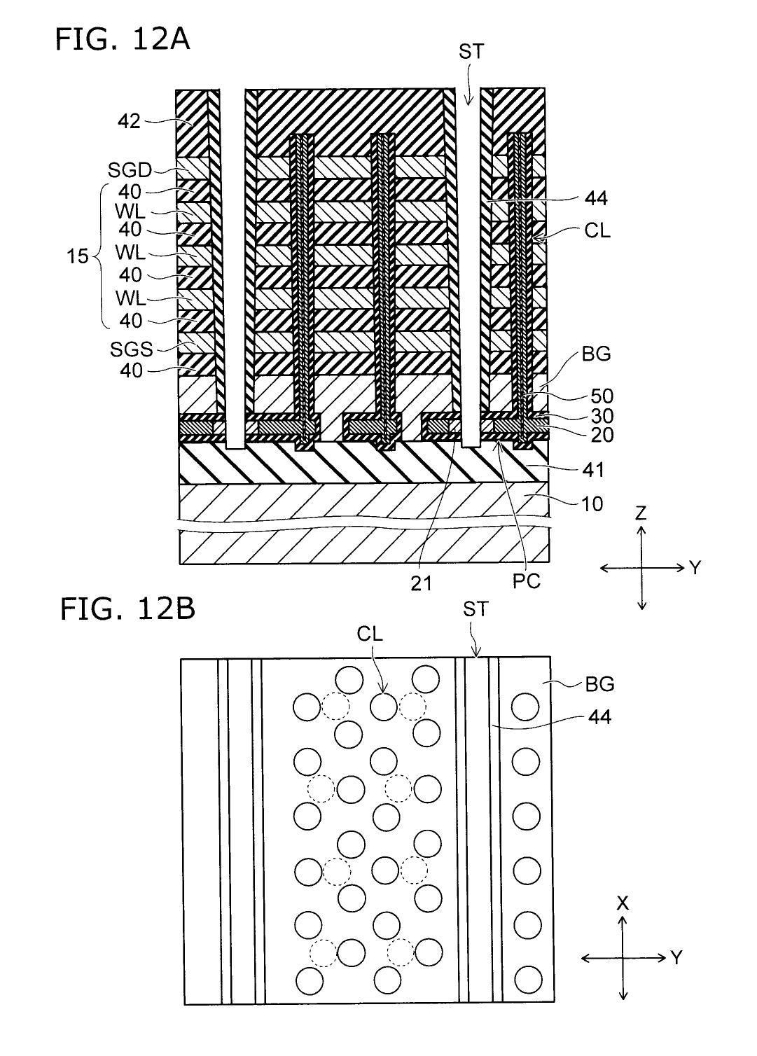

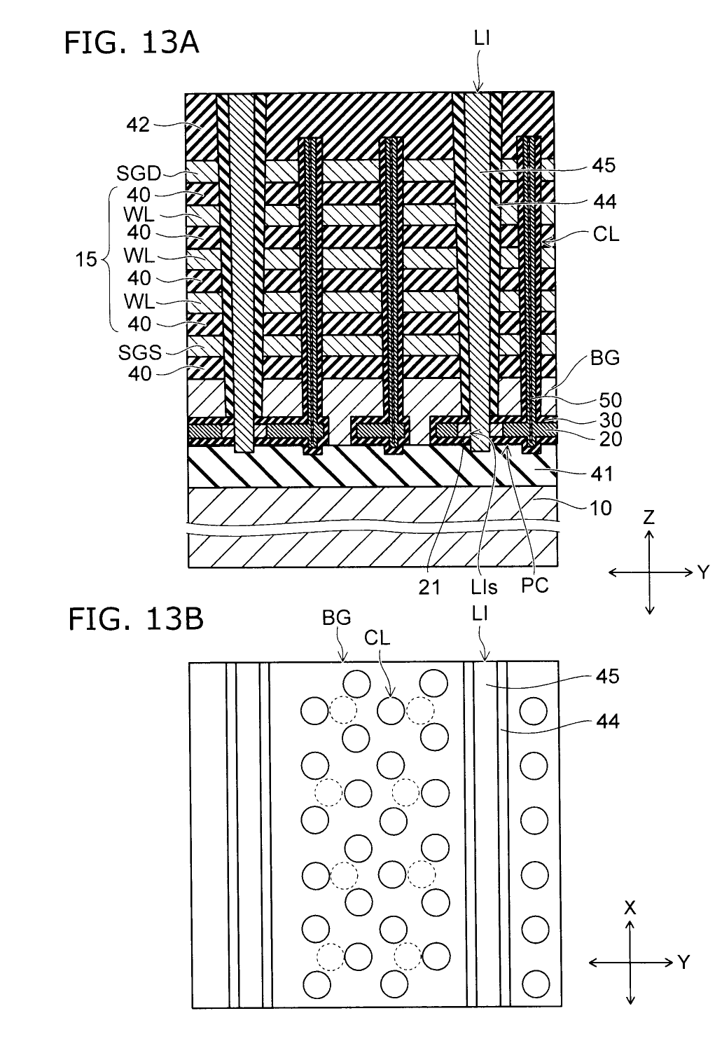

FIG. 4A, FIG. 5A, FIG. 6A, FIG. 7, FIG. 8A, FIG. 9A, FIG. 10A to FIG. 12A, and FIG. 13A are schematic cross-sectional views. FIG. 4B, FIG. 5B, FIG. 6B, FIG. 8B, FIG. 9B, FIG. 12B, and FIG. 13B are schematic plan views corresponding to an upper surface portion of the back gate BG in the respective schematic cross-sectional views described above.

As shown in FIG. 4A, the insulating layer 41 is formed on the substrate 10. The insulating layer 41 includes, for example, a silicon oxide film. In this case, for example, a peripheral circuit may be formed on the substrate 10.

A sacrificial layer 55 is formed on the insulating layer 41. Holes 55h are formed through the sacrificial layer 55. The holes 55h penetrate the sacrificial layer 55.

In a process described later, the sacrificial layer 55 is removed, and the coupling portion PC is formed in the removed portion (replacing process). Therefore, by forming the holes 55h, a pattern of the coupling portions PC is formed. As the sacrificial layer 55, for example, polysilicon is used.

As shown in FIG. 5A, the back gate BG is formed in the holes 55h and on the sacrificial layer 55. The periphery of the sacrificial layer 55 is covered with the back gate BG. The back gate BG includes, for example, a silicon film including boron.

The back gate BG formed in the hole 55h is used as a post to support the stacked body 15 in the replacing process described later. The back gate BG includes, for example, silicon doped with boron. With an electric field induced by the back gate BG, for example, a charge carrier layer can be induced in the channel body 20 in the coupling portion PC.

Thereafter, the stacked body 15 including a plurality of first layers 56 (sacrificial layers) and the insulating layers 40 (second layers) is formed on the back gate BG. The plurality of first layers 56 are separately stacked each other. The plurality of insulating layers 40 are each provided between the plurality of first layers 56. The plurality of first layers 56 and the plurality of insulating layers 40 are, for example, each alternately stacked.

The first layer 56 includes, for example, a silicon nitride film. In this case, the first layers 56 are removed by a replacing method described later, and the electrode layers WL are formed in the places from which the first layers 56 are removed.

For the first layer 56, a material including silicon and having conductivity may be used as the electrode layer WL from the beginning, without limiting to the sacrificial layer to be removed by the replacing method, or a material including a metal may be used. In this case, the source-side select gate SGS is formed in the lowermost layer of the stacked body 15, while the drain-side select gate SGD is formed in the uppermost layer of the stacked body 15. In this case, the replacing method described later may not be performed.

Thereafter, the insulating layer 42 is formed on the stacked body 15.

As shown in FIG. 6A, the memory holes MH penetrating the stacked body 15, the back gate BG, and the sacrificial layer 55 are formed. The memory hole MH is formed by, for example, a RIE method (Reactive Ion Etching) using a mask (not shown). For example, the memory hole MH may not penetrate the sacrificial layer 55, and it is sufficient for the memory hole to reach the sacrificial layer 55.

As shown in FIG. 7, the sacrificial layer 55 is removed by, for example, wet etching through the memory holes MH. Due to this, cavities 55a are formed inside the back gate BG. The cavity 55a is formed integrally with the memory hole MH. In this case, the back gate BG formed in the holes 55h supports the stacked body 15 and the like.

As shown in FIG. 8A, the films (the memory film 30, the film including the channel body 20, and the core insulating film 50) shown in FIG. 3A are successively formed on an inner wall (side wall and bottom portion) of the memory hole MH and an inner wall of the cavity 55a. Thereafter, the films formed on the insulating layer 42 are removed. Due to this, the columnar portion CL and the coupling portion PC are integrally formed.

For example, after the memory film 30 is formed on the inner wall of the cavity 55a, the channel body 20 is completely embedded. In this case, as shown in FIG. 3B, a maximum width W1 of the channel body 20 formed in the memory hole MH as viewed from the Z-direction is larger than a maximum width W2 of the channel body 20 formed in the cavity 55a in the Z-direction. Due to this, when the channel body 20 is formed through the memory hole MH, the channel body 20 in the memory hole MH is formed after forming the channel body 20 in the cavity 55a. That is, before forming the channel body 20 in the cavity 55a, the memory hole MH can be prevented from being closed with the channel body 20, so that the processing can be easily performed.

For example, after embedding the channel body 20 into the cavity 55a, the core insulating film 50 is formed in the memory hole MH. Due to this, the core insulating film 50 is not formed in the coupling portion PC.

Thereafter, the insulating layer 42 covering the top of the columnar portion CL is formed.

As shown in FIG. 9A, trenches ST penetrating the stacked body 15 and reaching the back gate BG are formed. As a method for forming the trench ST, for example, a RIE method using a mask (not shown) is used. As shown in FIG. 9B, the trench ST is formed to extend in the X-direction. The back gate BG is exposed in a bottom surface of the trench ST.

As shown in FIG. 10A, the first layers 56 are removed by, for example, wet etching through the trenches ST to form cavities 40a. In this case, since the columnar portions CL support the insulating layers 40 and the like of the stacked body 15, the stacked body 15 does not collapse.

As shown in FIG. 10B, the electrode layers WL, the source-side select gate SGS, and the drain-side select gate SGD are formed in the cavities 40a through the trenches ST. Thereafter, the electrode layers WL, the source-side select gate SGS, and the drain-side select gate SGD that are formed at a side wall of the trench ST are etched back. Due to this, it is possible to prevent contact among the electrode layers WL, the source-side select gate SGS, and the drain-side select gate SGD

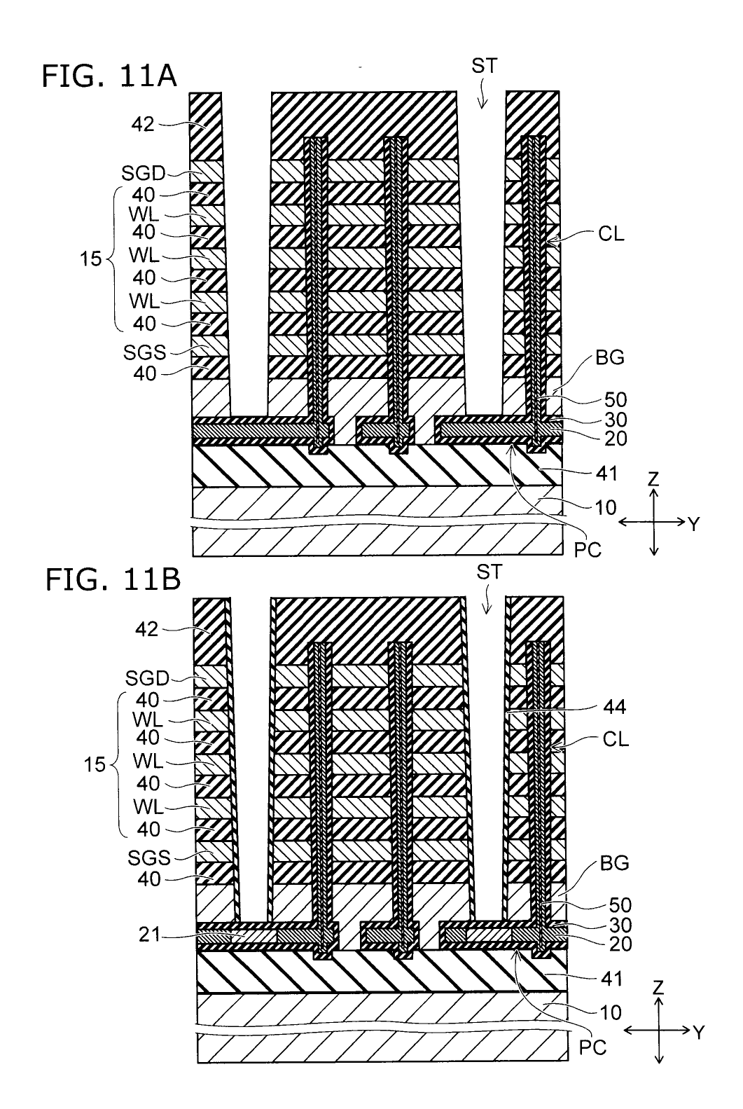

As shown in FIG. 11A, the trench ST is formed to an upper surface of the coupling portion PC by etching the back gate BG exposed in the bottom surface of the trench ST. The memory film 30 formed in the coupling portion PC is exposed in the bottom surface of the trench ST.

As shown in FIG. 11B, the insulating film 44 is formed on an inner wall of the trench ST. The insulating film 44 includes, for example, a silicon oxide film.

Thereafter, the impurity layer 21 is formed in the channel body 20 in the coupling portion PC via the trench ST by, for example, an ion implantation method. The impurity concentration of the impurity layer 21 is higher than the impurity concentration of the channel body 20. In this case, it is possible, with the insulating film 44 formed on the side wall of the trench ST as described above, to prevent reaction of the electrode layer WL due to ion implantation.

As shown in FIG. 12A, the insulating film 44 is further formed thicker inside the insulating film 44 on the inner wall of the trench ST.

Thereafter, the bottom surface of the trench ST is further removed, so that the trench ST penetrating the channel body 20 in the coupling portion PC is formed. For example, the trench ST penetrates the coupling portion PC and reaches the insulating layer 41. For example, the trench ST may penetrate the channel body 20 in the coupling portion PC and reach the memory film 30.

Due to this, the impurity layer 21 is exposed in the trench ST. The exposed portion of the impurity layer 21 is formed at a side surface of the trench ST higher than the bottom surface thereof.

As shown in FIG. 13A, the conductive film 45 is formed in the trench ST. The conductive film 45 includes, for example, at least any of tungsten, titanium, and titanium nitride. Due to this, the interconnect portion LI including the side surface LIs in contact with the impurity layer 21 is formed.

The conductive film 45 is formed at the side surface LIs of the interconnect portion LI, while the insulating film 44 is not formed thereat. Therefore, the interconnect portion LI is in contact with the impurity layer 21, and the interconnect portion LI is electrically connected with the channel body 20 via the side surface LIs.

Thereafter, as shown in FIG. 2A, the contact portion CN is formed on the columnar portion CL, and an interconnect layer and the like are formed as necessary. Due to this, the semiconductor memory device of the embodiment is formed.

For example, in some cases, the channel body 20 in the coupling portion PC is in contact with the bottom surface of the interconnect portion LI and electrically connected with the interconnect portion LI. In this case, the bottom surface of the interconnect portion LI needs to be formed in the coupling portion PC, which may give rise to a problem of processing accuracy or the like.

In contrast, according to the embodiment, the channel body 20 of the coupling portion PC is electrically connected with the interconnect portion LI via the side surface LIs. Therefore, compared to the case where the bottom surface of the interconnect portion LI is used as a contact with the channel body 20, it is easy to form the interconnect portion LI. Due to this, it is possible, while realizing the higher reliability or miniaturization of a memory device, to reduce a block size or increase a cell current, so that the possibility of high-speed operation can be enlarged. Moreover, it is possible, by forming the above structure, to dispose a peripheral circuit below a cell region, so that the chip size can be reduced. Further, it is possible to suppress an increase in the degree of difficulty in processing with the miniaturization of the device.

In addition to the above, as shown in FIG. 3B for example, the maximum width W1 of the channel body 20 in the stacked body 15 as viewed from the Z-direction is larger than the maximum width W2 of the channel body 20 in the coupling portion PC in the Z-direction. Due to this, the channel body 20 is easily formed in the manufacturing process of the coupling portion PC. Therefore, it is possible to further suppress an increase in the degree of difficulty in processing with the miniaturization of the device.

It is sufficient for the interconnect portion LI to penetrate the channel body 20 in the coupling portion PC, and the interconnect portion LI may optionally reach the insulating layer 41.

### Another Embodiment

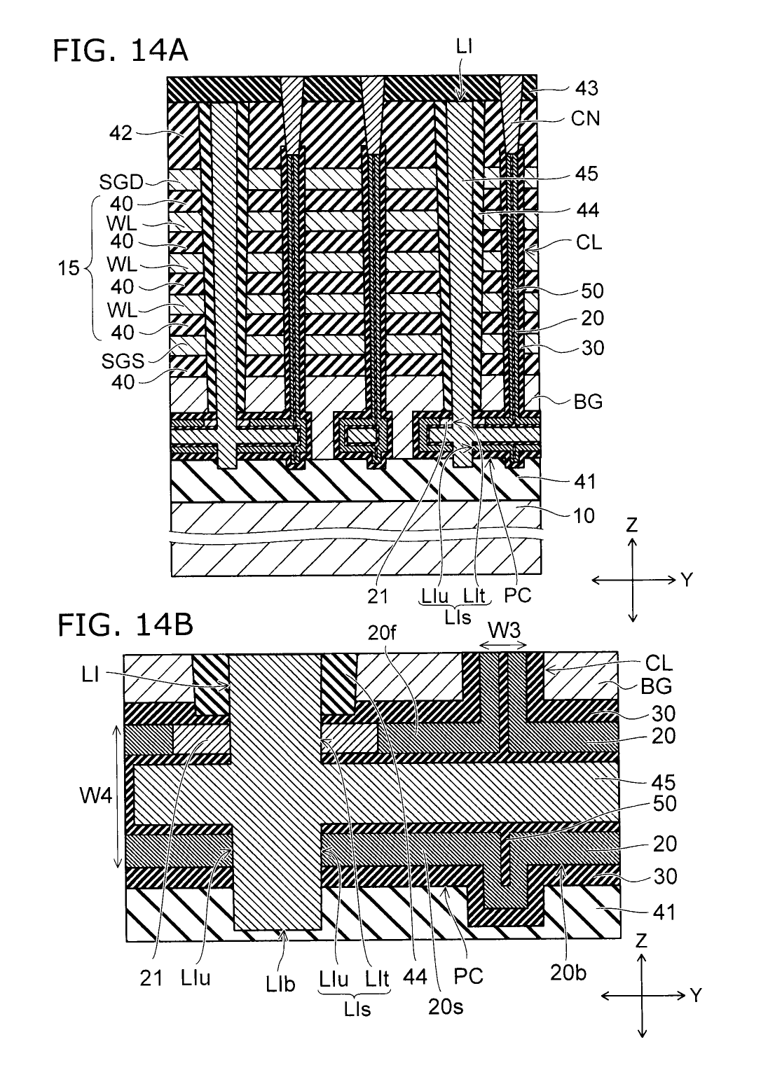

FIG. 14A is a schematic cross-sectional view of a portion of the memory string MS of another embodiment; and FIG. 14B is an enlarged schematic cross-sectional view of a portion of the memory string MS of the embodiment.

The embodiment differs from the embodiment described above in that the thickness of the coupling portion PC is increased. Due to this, a space (the conductive film 45 in FIG. 14A and FIG. 14B) is provided inside the channel body 20 in the coupling portion PC.

In this case, the channel body 20 in the coupling portion PC is provided on the stacked body 15 side (upper side) and the substrate 10 side (lower side) with the space interposed therebetween. Therefore, at a portion where the interconnect portion LI is in contact with the coupling portion PC, the channel body 20 (first semiconductor region 20f) provided on the upper side of the coupling portion PC is separated from the channel body 20 (second semiconductor region 20s) provided on the lower side. A description of portions similar to those of the embodiment described above is omitted.

As shown in FIG. 14A and FIG. 14B, the side surface LIs of the interconnect portion LI includes an upper portion LIt and a lower portion LIu.

The upper portion LIt is provided with the conductive film 45 but not provided with the insulating film 44. Therefore, the upper portion LIt is in contact with the impurity layer 21 of the coupling portion PC. That is, the channel body 20 is electrically connected with the upper portion LIt of the interconnect portion LI via the impurity layer 21.

The lower portion LIu is provided on the substrate 10 side of the upper portion LIt and separated from the upper portion LIt. The lower portion LIu is provided with the conductive film 45 but not provided with the insulating film 44. Therefore, the lower portion LIu is in contact with the channel body 20 provided on the lower side of the coupling portion PC. That is, the impurity layer 21 of the coupling portion PC is provided only between the channel body 20 and the side surface LIs. Moreover, the impurity layer 21 is separated from the channel body 20 in contact with the lower portion LIu.

The conductive film 45 extending from, for example, the interconnect portion LI into the coupling portion PC is provided between the upper portion LIt and the lower portion LIu of the interconnect portion LI. The conductive film 45 is provided integrally from the interconnect portion LI to the coupling portion PC.

The conductive film 45 extending into the coupling portion PC is provided inside the channel body 20 via the core insulating film 50. That is, the channel body 20 on the upper side, which includes the impurity layer 21 in contact with the upper portion LIt, is separated from the channel body 20 on the lower side, which is in contact with the lower portion LIu.

The core insulating film 50 is provided inside the channel body 20 of the coupling portion PC. The conductive film 45 is provided inside the core insulating film 50. The conductive film 45 is provided in the coupling portion PC without gaps. The channel body 20, the core insulating film 50, and the conductive film 45 that are provided in the coupling portion PC extend in the X-direction and the Y-direction.

The impurity layer 21 provided in the coupling portion PC extends in the X-direction along the upper portion LIt. The impurity concentration of the impurity layer 21 is higher than the impurity concentration of the channel body 20 in contact with the lower portion LIu.

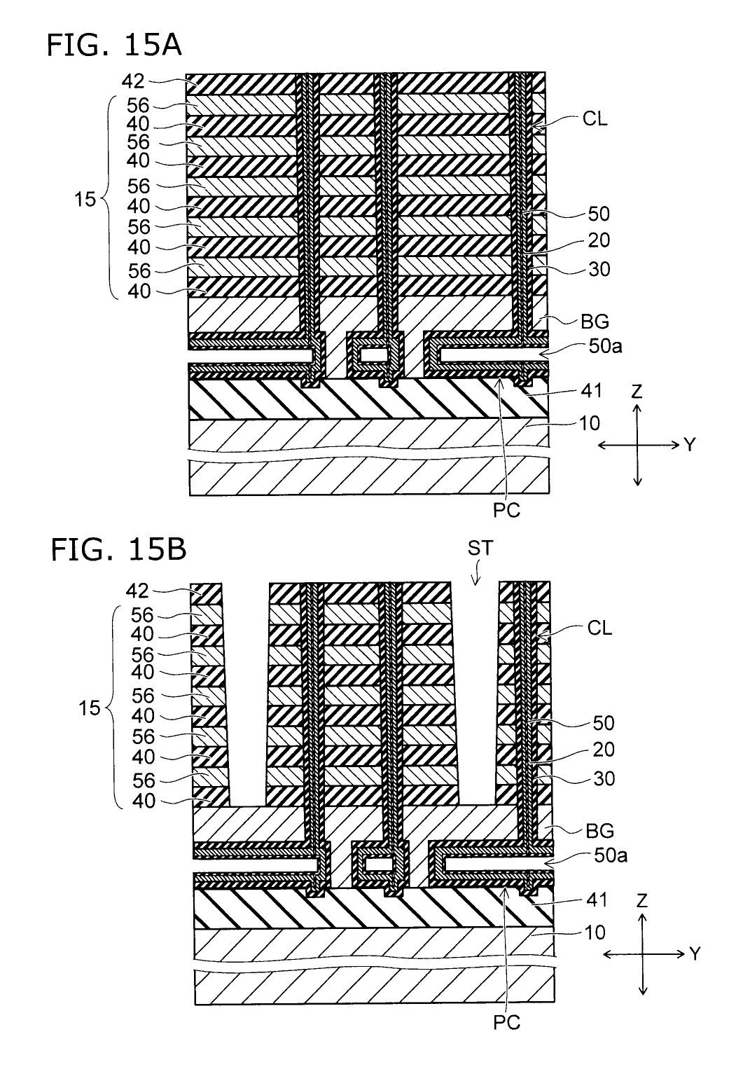

Next, a method for manufacturing a semiconductor memory device of the embodiment, which has been described with reference to FIG. 14A and FIG. 14B, will be described with reference to FIG. 15A to FIG. 18B.

For a manufacturing method up to FIG. 15A, a method similar to that in FIG. 4A to FIG. 7 described above is used.

As shown in FIG. 4A, the insulating layer 41 is formed on the substrate 10. The insulating layer 41 includes, for example, a silicon oxide film. The sacrificial layer 55 is formed on the insulating layer 41. The holes 55h are formed through the sacrificial layer 55. The holes 55h penetrate the sacrificial layer 55. In this case, for example, a peripheral circuit may be formed on the substrate 10. As the sacrificial layer 55, for example, polysilicon is used.

As shown in FIG. 5A, the back gate BG is formed in the holes 55h and on the sacrificial layer 55. The periphery of the sacrificial layer 55 is covered with the back gate BG.

Thereafter, the stacked body 15 including the plurality of first layers 56 (sacrificial layers) and the insulating layers 40 (second layers) is formed on the back gate BG. The plurality of first layers 56 are separately stacked each other. The plurality of insulating layers 40 are each provided between the plurality of first layers 56. The plurality of first layers 56 and the plurality of insulating layers 40 are, for example, each alternately stacked. The first layer 56 includes, for example, a silicon nitride film.

As shown in FIG. 6A, the memory holes MH penetrating the stacked body 15, the back gate BG, and the sacrificial layer 55 are formed. The memory holes MH are formed by, for example, a RIE method using a mask (not shown). For example, the memory hole MH may not penetrate the sacrificial layer 55, and it is sufficient for the memory hole to reach the sacrificial layer 55.

As shown in FIG. 7, the sacrificial layer 55 is removed by, for example, wet etching through the memory holes MH. Due to this, cavities 55a are formed inside the back gate BG.

As shown in FIG. 15A, the films shown in FIG. 3A are successively formed on the inner wall of the memory hole MH and the inner wall of the cavity 55a. The cavity 55a is not completely filled, and a space 50a is formed therein. Thereafter, the films formed on the insulating layer 42 are removed. Due to this, the columnar portion CL and the coupling portion PC are integrally formed.

For example, as shown in FIG. 14B, a maximum width W3 of the channel body 20 formed in the memory hole MH as viewed from the Z-direction is smaller than a maximum width W4 of the channel body 20 formed in the cavity 55a. Due to this, when the core insulating film 50 is formed inside the channel body 20 through the memory hole MH, the core insulating film 50 in the memory hole MH is first formed before the core insulating film 50 is completely embedded in the cavity 55a. That is, the space 50a can be formed in the cavity 55a, so that the processing can be made easy.

Thereafter, the insulating layer 42 covering the columnar portion CL is formed.

As shown in FIG. 15B, the trenches ST penetrating the stacked body 15 and reaching the back gate BG are formed. As a method for forming the trench ST, for example, a RIE method using a mask (not shown) is used. The back gate BG is exposed in the bottom surface of the trench ST.

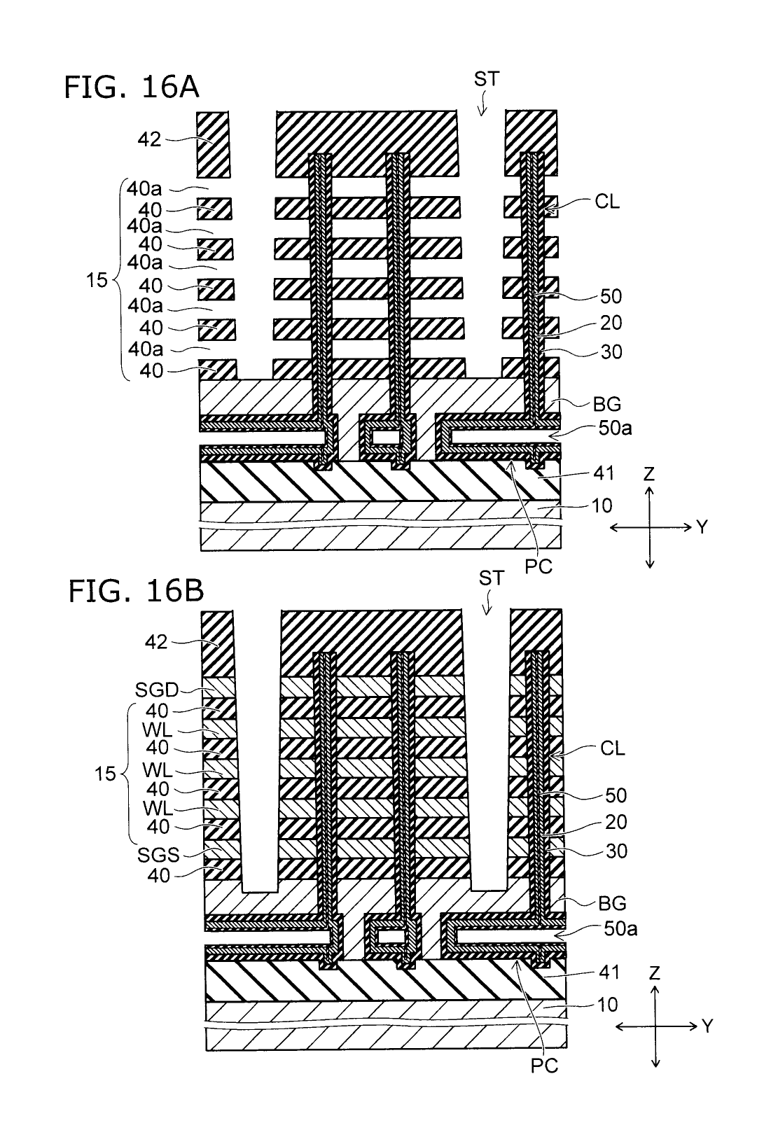

As shown in FIG. 16A, the first layers 56 are removed through the trenches ST to form the cavities 40a.

As shown in FIG. 16B, the electrode layers WL, the source-side select gate SGS, and the drain-side select gate SGD are formed through the trenches ST. Thereafter, the electrode layers WL, the source-side select gate SGS, and the drain-side select gate SGD that are formed at the side wall of the trench ST are etched back.

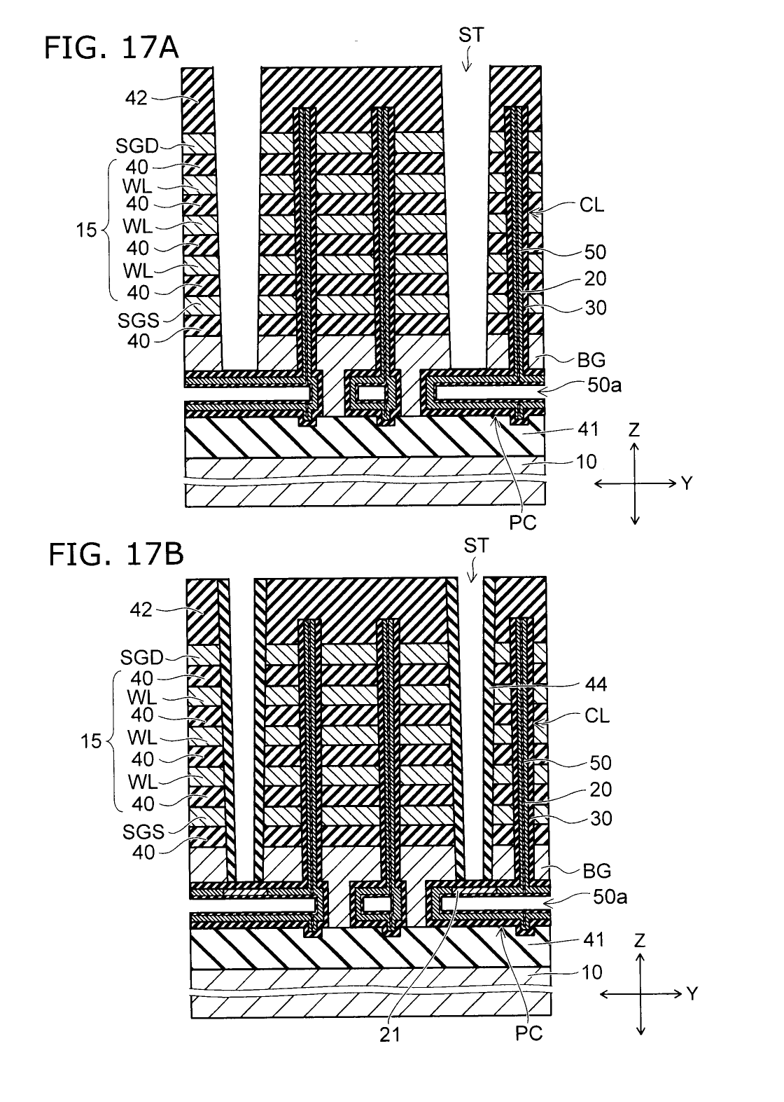

As shown in FIG. 17A, the trench ST is formed to the upper surface of the coupling portion PC by etching the back gate BG exposed in the bottom surface of the trench ST. The memory film 30 is exposed in the bottom surface of the trench ST.

As shown in FIG. 17B, the insulating film 44 is formed on the inner wall of the trench ST. The insulating film 44 includes, for example, a silicon oxide film.

Thereafter, the impurity layer 21 is formed only in the channel body 20 formed on the upper side of the space 50a in the coupling portion PC via the trench ST by, for example, an ion implantation method.

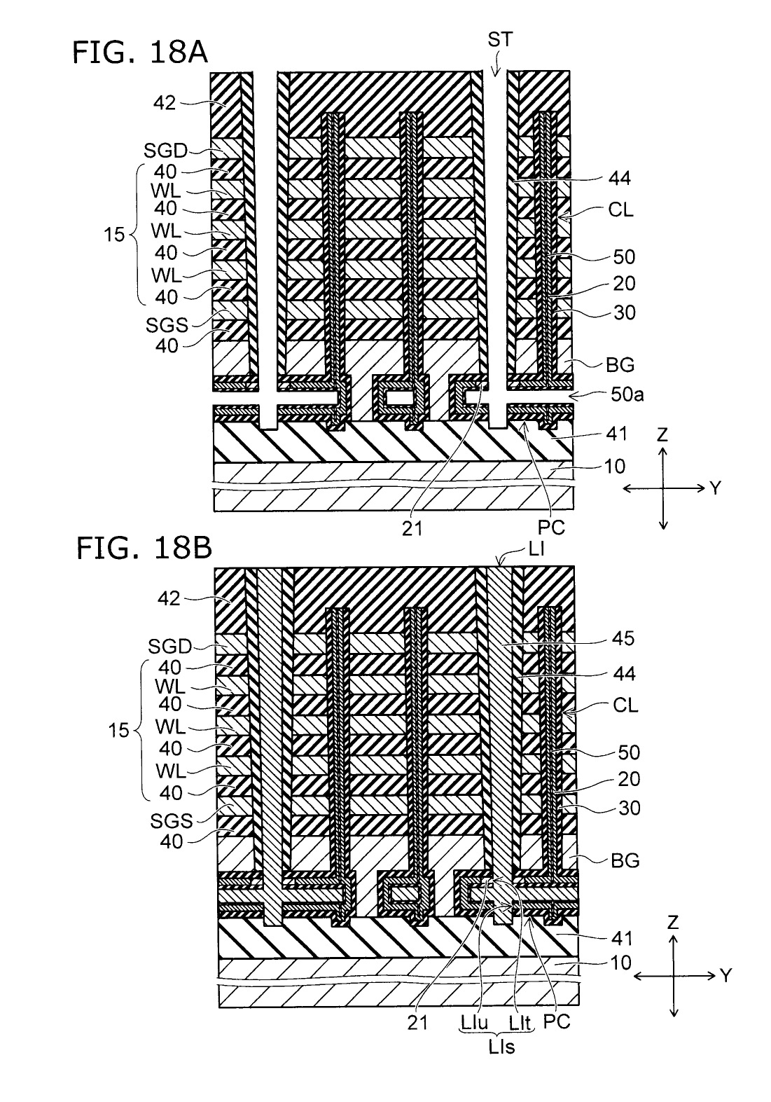

As shown in FIG. 18A, the insulating film 44 is further formed thicker inside the insulating film 44 on the inner wall of the trench ST.

Thereafter, the bottom surface of the trench ST is further removed, so that the trench ST penetrates the channel body 20 in the coupling portion PC. For example, the trench ST penetrates the coupling portion PC and reaches the insulating layer 41. For example, the trench ST may penetrate the channel body 20 in the coupling portion PC and reach the memory film 30.

Due to this, the impurity layer 21 of the coupling portion PC, the space 50a, and the channel body 20 formed on the lower side of the space 50a are exposed in the trench ST. The exposed portion of the impurity layer 21 is formed at a higher level than the bottom surface of the trench ST. The impurity layer 21 is separated from the channel body 20 formed on the lower side via the space 50a.

As shown in FIG. 18B, the conductive film 45 is formed in the trench ST and the space 50a. The conductive film 45 includes, for example, at least any of tungsten, titanium, and titanium nitride. Due to this, the interconnect portion LI including the side surface LIs is formed. The side surface LIs includes the upper portion LIt and the lower portion LIu formed on the substrate 10 side of the upper portion LIt.

The upper portion LIt is in contact with the impurity layer 21. The lower portion LIu is in contact with the channel body 20 formed on the lower side of the space 50a. The conductive film 45 formed between the upper portion LIt and the lower portion LIu extends inside the core insulating film 50 in the coupling portion PC, and is formed integrally with the interconnect portion LI. The conductive film 45 formed inside the core insulating film 50 may include, for example, an air gap.

The conductive film 45 is formed at the side surface LIs of the interconnect portion LI, that is, at the upper portion LIt and the lower portion LIu, but the insulating film 44 is not formed thereat. Therefore, the interconnect portion LI is electrically connected with the channel body 20 via the upper portion LIt.

Thereafter, as shown in FIG. 2A, the contact portion CN is formed on the columnar portion CL, and an interconnect layer and the like are formed as necessary. Due to this, the semiconductor memory device of the embodiment is formed.

According to the embodiment, the channel body 20 of the coupling portion PC is electrically connected with the interconnect portion LI via the upper portion LIt of the side surface LIs, similarly to the embodiment described above. Therefore, compared to the case where the bottom surface of the interconnect portion LI is used as a contact with the channel body 20, it is easy to form the interconnect portion LI. Due to this, it is possible, while realizing the higher reliability or miniaturization of a memory device, to reduce a block size or increase a cell current, so that the possibility of high-speed operation can be enlarged. Moreover, it is possible to dispose a peripheral circuit below a cell region, so that the chip size can be reduced. Further, it is possible to suppress an increase in the degree of difficulty in processing with the miniaturization of the device.

In addition to the above, according to the embodiment, the space 50a is formed inside the channel body 20 of the coupling portion PC.

For example, in some cases, the channel body 20 provided on the upper side of the coupling portion PC is in contact with the channel body 20 provided on the lower side. In this case, there is the possibility that the agglomeration occurs in the channel body 20 inside the coupling portion PC and thus the channel body 20 is divided.

In contrast, according to the embodiment, the channel body 20 and the impurity layer 21 that are provided on the upper side of the coupling portion PC are separated from the channel body 20 provided on the lower side, at a contact forming portion between the interconnect portion LI and the coupling portion PC. Due to this, it is possible to suppress the occurrence of disconnection or the like of the channel body 20. Therefore, it is possible to further suppress an increase in the degree of difficulty in processing with the miniaturization of the device.

In addition to the above, as shown in FIG. 14B for example, the maximum width W3 of the channel body 20 in the stacked body 15 as viewed from the Z-direction is smaller than, for example, the maximum width W4 of the channel body 20 of the coupling portion PC in the Z-direction. Due to this, the space can be easily formed inside the channel body 20 in the manufacturing process of the coupling portion PC. Therefore, it is possible to further suppress an increase in the degree of difficulty in processing with the miniaturization of the device.

The conductive film 45 extending from the interconnect portion LI may not be provided inside the channel body 20 in the coupling portion PC, and, for example, the core insulating film 50 or an air gap may be provided therein.

For example, the bottom surface of the interconnect portion LI may be located on the lower side of the channel body 20 of the coupling portion PC, and may be covered with the memory film 30.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a substrate;
a conductive layer provided on the substrate;
a stacked body provided on the conductive layer and including a plurality of electrode layers separately stacked each other;
a coupling portion provided in the conductive layer;
a semiconductor portion provided integrally in the stacked body and in the coupling portion;
a charge storage film provided between the semiconductor portion and the plurality of electrode layers; and
an interconnect portion provided integrally in the stacked body and in the conductive layer and extending in a stacking direction of the stacked body,
the interconnect portion including a side surface provided in the conductive layer,
the side surface being in contact with an entire side surface of the semiconductor portion in the coupling portion.

2. The device according to claim 1, wherein
the semiconductor portion includes an impurity layer in contact with the side surface of the interconnect portion,
an impurity concentration of the impurity layer is higher than an impurity concentration of the semiconductor portion, and
the semiconductor portion is electrically connected with the interconnect portion via the impurity layer.

3. The device according to claim 1, wherein
a maximum width of the semiconductor portion in the stacked body as viewed from the stacking direction is larger than a maximum width of the semiconductor portion in the coupling portion in the stacking direction.

4. The device according to claim 1, further comprising an insulating film provided inside the semiconductor portion and extending in the stacking direction.

5. The device according to claim 4, wherein
the insulating film is separated from the interconnect portion.

6. The device according to claim 4, wherein
the insulating film is provided inside the semiconductor portion in the coupling portion and extends in a direction crossing the stacking direction, and
the semiconductor portion in the coupling portion is in contact with the interconnect portion and interposes the insulating film in the stacking direction.

7. The device according to claim 6, wherein
the interconnect portion includes a conductive film provided integrally in the stacked body and inside the insulating film of the coupling portion.

8. The device according to claim 7, wherein
the side surface of the interconnect portion includes:
an upper portion provided on the stacked body side of the conductive film provided in the coupling portion; and
a lower portion provided on the substrate side of the conductive film provided in the coupling portion,
the semiconductor portion includes an impurity layer in contact with the upper portion,
an impurity concentration of the impurity layer is higher than an impurity concentration of the semiconductor portion, and
the semiconductor portion is electrically connected with the interconnect portion via the impurity layer.

9. The device according to claim 8, wherein
the lower portion of the interconnect portion is in contact with the semiconductor portion, the semiconductor portion has an impurity concentration being lower than the impurity concentration of the impurity layer.

10. The device according to claim 6, wherein
a maximum width of the semiconductor portion in the stacked body as viewed from the stacking direction is smaller than a maximum width of the semiconductor portion in the coupling portion in the stacking direction.

11. A semiconductor memory device comprising:
a substrate;
a conductive layer provided on the substrate;
a stacked body provided on the conductive layer and including a plurality of electrode layers separately stacked each other;
a semiconductor pillar portion provided along a stacking direction of the stacked body;
an interconnect portion provided along the stacking direction of the stacked body and including a first lower surface;
a semiconductor portion connected with the interconnect portion and the semiconductor pillar portion, the semiconductor portion provided in the conductive layer with an insulating film between the semiconductor portion and the conductive layer, the semiconductor portion including a second lower surface having a height being higher than a height of the first lower surface, the semiconductor portion provided integrally with the semiconductor pillar portion; and
a charge storage film provided between the semiconductor pillar portion and one of the plurality of electrode layers.

12. The device according to claim 11, wherein
the semiconductor portion is connected at a side surface of the interconnect portion with the interconnect portion.

13. The device according to claim 12, wherein
the semiconductor portion includes an impurity layer in contact with the side surface of the interconnect portion,
an impurity concentration of the impurity layer is higher than an impurity concentration of the semiconductor pillar portion, and
the semiconductor portion is electrically connected with the interconnect portion via the impurity layer.

14. The device according to claim 11, wherein
the interconnect portion is not connected with the semiconductor portion at the first lower surface.

15. The device according to claim 12, further comprising
an insulating layer provided between the substrate and the conductive layer, wherein
the first lower surface is provided in contact with the insulating layer.

16. The device according to claim 12, wherein
a maximum width of the semiconductor pillar portion as viewed from the stacking direction is longer than a maximum width of the semiconductor portion in the stacking direction.

17. The device according to claim 11, wherein
the semiconductor portion includes:
a first semiconductor region provided in the conductive layer with the insulating film between the semiconductor region and the conductive layer and connected at a side surface of the interconnect portion with the interconnect portion; and
a second semiconductor region including the second lower surface and connected at the side surface of the interconnect portion with the interconnect portion separated from the first semiconductor region.

18. The device according to claim 17, wherein
the first semiconductor region includes an impurity layer in contact with the side surface of the interconnect portion,
an impurity concentration of the impurity layer is higher than an impurity concentration of the semiconductor pillar portion, and
the semiconductor portion is electrically connected with the interconnect portion via the impurity layer.

19. A method for manufacturing a semiconductor memory device, comprising:
forming a sacrificial layer on a substrate;
forming a conductive layer on the substrate and on the sacrificial layer;
forming, on the conductive layer, a stacked body including a plurality of first layers separately stacked each other;
forming a hole penetrating the stacked body and the conductive layer and reaching the sacrificial layer;
removing the sacrificial layer through the hole to form a cavity;
forming, on an inner wall of the hole and an inner wall of the cavity, a film including a charge storage film;
forming a semiconductor portion inside the film including the charge storage film;
forming a trench penetrating the stacked body, the conductive layer, and the semiconductor portion in the cavity; and
forming, inside the trench, a conductive film to be electrically connected with the semiconductor portion via a side surface of the trench.

20. The method according to claim 19, wherein
the forming of the trench includes
forming a trench penetrating the stacked body and the conductive layer and reaching an upper surface of the film including the charge storage film in the cavity,
forming, in the semiconductor portion in the cavity through the trench, an impurity layer having an impurity concentration higher than an impurity concentration of the semiconductor portion, and
causing the trench to penetrate the semiconductor portion.
